(19) United States
(12) Patent Application Publication
(10) Pub. No.: US 2024/0040882 A1
(43) Pub. Date: Feb. 1, 2024

(54) DISPLAY PANEL

(71) Applicant: WUHAN CHINA STAR OPTOELECTRONICS SEMICONDUCTOR DISPLAY TECHNOLOGIES CO., LTD., Wuhan, Hubei (CN)

(72) Inventor: Jing Zhou, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/610,977

(22) PCT Filed: Sep. 17, 2021
(86) PCT No.: PCT/CN2021/118990

§ 371 Date: Mar. 16, 2023

(30) Foreign Application Priority Data
Sep. 10, 2021 (CN) 202111063532.6

(51) Int. Cl. H10K 59/38; H10K 59/122; H10K 59/80

(52) U.S. Cl. CPC H10K 59/38; H10K 59/122; H10K 59/8792

(57) ABSTRACT

A display panel. The display panel includes a light-emitting device layer and a color filter layer disposed on the light-emitting device layer, wherein the color filter layer includes a light-shielding layer, a first color resist layer, and a second color resist layer, the light-shielding layer includes a plurality of first openings arranged corresponding to the first pixel openings, the second color resist layer includes a plurality of second openings, and overlapping portions of the first openings and the second openings form light-transmitting openings of the color filter layer.

### BACKGROUND OF INVENTION

### Field of Invention

The present application relates to a field of display technology, in particular to a display panel.

### Description of Prior Art

In an organic light-emitting diode (OLED) display panel, a polarizer can effectively reduce a reflectivity of the OLED display panel under strong light, but it causes the OLED display panel to lose nearly 58% of the light output, which greatly increases a service life burden of the OLED display panel, and a thickness of the polarizer is about 100 μm, which is large, and its material is brittle, which is not conducive to development of dynamic bending products.

In order to develop the dynamic bending products based on the OLED display panel, the OLED display panel is usually manufactured by POL-less technology. The POL-less technology refers to a use of color filters (CFs) instead of polarizers. The color filter is composed of a red color resister, a green color resister, a blue color resister, and a black matrix (BM). In the OLED display panel, the red color resister, the green color resister, and the blue color resister respectively responsible for light output of a red sub-pixel unit, a green sub-pixel unit, and a blue sub-pixel unit, and the black matrix is mainly responsible for preventing light leakage of the OLED display panel and reducing a reflectivity of the OLED display panel.

The color filter not only can reduce the reflectivity of the OLED display panel under strong light to a certain extent, but also can increase a light output rate of the OLED display panel from 42% to 60%. However, compared with the polarizer, a photoresist of the color filter technology has higher requirements for materials and manufacturing processes, which has a great impact on yield and cost of the OLED panel.

In the prior art, the OLED display panel manufactured by the POL-less technology has a phenomenon of color separation.

Therefore, there is an urgent need at present to solve the problem of the color separation phenomenon of the OLED display panel manufactured by the POL-less technology in the prior art.

### SUMMARY OF INVENTION

An object of the present application is to provide a display panel to alleviate problems of poor shape uniformity of openings formed by the light-shielding layer and being easy to produce irregular edges or rough edges, and to further solve the color separation phenomenon of the OLED display panel manufactured by the POL-less technology in the prior art.

In order to solve the above problem, the present application provides a display panel, which includes: a substrate; a pixel definition layer disposed on a side of the substrate, wherein the pixel definition layer includes a plurality of first pixel openings; a light-emitting layer disposed on a side of the pixel definition layer away from the substrate, wherein the light-emitting layer includes a plurality of first light-emitting pixel units displaying a first color and a plurality of second light-emitting pixel units displaying a second color, and the first light-emitting pixel units are arranged corresponding to the first pixel openings; and a color filter layer disposed on the side of the pixel definition layer away from the substrate, wherein the color filter layer includes a light-shielding layer, and the light-shielding layer includes a plurality of first openings arranged corresponding to the first pixel openings,
wherein the color filter layer further includes: a first color resist layer allowing transmittance of the first color and a second color resist layer allowing transmittance of the second color, the first color resist layer is at least disposed at the first openings corresponding to the first pixel openings, the second color resist layer is disposed on a side of the light-shielding layer away from the substrate, the second color resist layer and the first color resist layer overlap or contact with the light-shielding layer, the second color resist layer is also provided with second openings corresponding to the first pixel openings, and overlapping portions of the first openings and the second openings form light-transmitting openings of the color filter layer.

In some embodiments, a top view pattern of each of the light-transmitting openings of the color filter layer includes a circle or a quasi-circular polygon, the quasi-circular polygon includes a plurality of sides and a plurality of inflection points connecting adjacent ones of the sides, the quasi-circular polygon further includes a center point, and distances from the center point to the plurality of inflection points are all equal.

In some embodiments, a boundary line of an orthographic projection of one of the second openings on the display panel and a boundary line of an orthographic projection of one of the first openings on the display panel have a plurality of intersections, an orthographic projection of one of the light-transmitting openings on the display panel includes a center point, and distances from the plurality of intersections to the center point are all equal.

In some embodiments, the first color resist layer is disposed on a side of the second color resist layer away from the substrate, or the first color resist layer is disposed between the second color resist layer and the light-shielding layer, and the first color resist layer at least covers an area corresponding to the light-transmitting openings.

In some embodiments, orthographic projections of the second openings on the display panel are located within orthographic projections of the first openings on the display panel.

In some embodiments, a top view pattern of each of the second openings includes a circle or a quasi-circular polygon, and the quasi-circular polygon includes a plurality of sides and a plurality of inflection points connecting adjacent ones of the sides, the quasi-circular polygon further includes a center point, and distances from the center point to the plurality of inflection points are all equal.

In some embodiments, the first color resist layer is disposed on a side of the second color resist layer away from the substrate, or the first color resist layer is disposed between the second color resist layer and the light-shielding layer, and the first color resist layer covers at least an area corresponding to the second openings.

In some embodiments, the second color resist layer partially overlaps the light-shielding layer, and the second color resist layer partially overlaps the first color resist layer.

In some embodiments, at least part of an orthographic projection of the second color resist layer on the display panel is outside the orthographic projections of the first openings on the display panel, and at least part of an orthographic projection of the first color resist layer on the display panel is outside the orthographic projections of the second openings on the display panel.

In some embodiments, light transmittance of the light-transmitting openings of the color filter layer is greater than or equal to 40%, and the light-shielding layer includes a material with an optical density greater than or equal to 1.5.

The present application also provides a display panel, which includes: a substrate; a pixel definition layer disposed on a side of the substrate, wherein the pixel definition layer includes a plurality of first pixel openings; a light-emitting layer disposed on a side of the pixel definition layer away from the substrate, wherein the light-emitting layer includes a plurality of first light-emitting pixel units displaying a first color and a plurality of second light-emitting pixel units displaying a second color, and the first light-emitting pixel units are arranged corresponding to the first pixel openings; and a color filter layer disposed on the side of the pixel definition layer away from the substrate, wherein the color filter layer includes a light-shielding layer, and the light-shielding layer includes a plurality of first openings arranged corresponding to the first pixel openings,
wherein the color filter layer further includes: a first color resist layer allowing transmittance of the first color and a second color resist layer allowing transmittance of the second color, the first color resist layer is at least disposed at the first openings corresponding to the first pixel openings, the second color resist layer is disposed on a side of the light-shielding layer away from the substrate, the second color resist layer and the first color resist layer overlap or contact with the light-shielding layer, the second color resist layer is also provided with second openings corresponding to the first pixel openings, and overlapping portions of the first openings and the second openings form light-transmitting openings of the color filter layer; and
wherein the first light-emitting pixel units are located in the first pixel openings, and the first pixel openings are greater than or equal to the light-transmitting openings of the color filter layer.

In some embodiments, a top view pattern of each of the light-transmitting openings of the color filter layer includes a circle or a quasi-circular polygon, the quasi-circular polygon includes a plurality of sides and a plurality of inflection points connecting adjacent ones of the sides, the quasi-circular polygon further includes a center point, and distances from the center point to the plurality of inflection points are all equal.

In some embodiments, a boundary line of an orthographic projection of one of the second openings on the display panel and a boundary line of an orthographic projection of one of the first openings on the display panel have a plurality of intersections, an orthographic projection of one of the light-transmitting openings on the display panel includes a center point, and distances from the plurality of intersections to the center point are all equal.

In some embodiments, the first color resist layer is disposed on a side of the second color resist layer away from the substrate, or the first color resist layer is disposed between the second color resist layer and the light-shielding layer, and the first color resist layer at least covers an area corresponding to the light-transmitting openings.

In some embodiments, orthographic projections of the second openings on the display panel are located within orthographic projections of the first openings on the display panel.

In some embodiments, a top view pattern of each of the second openings includes a circle or a quasi-circular polygon, and the quasi-circular polygon includes a plurality of sides and a plurality of inflection points connecting adjacent ones of the sides, the quasi-circular polygon further includes a center point, and distances from the center point to the plurality of inflection points are all equal.

In some embodiments, the first color resist layer is disposed on a side of the second color resist layer away from the substrate, or the first color resist layer is disposed between the second color resist layer and the light-shielding layer, and the first color resist layer covers at least an area corresponding to the second openings.

In some embodiments, the second color resist layer partially overlaps the light-shielding layer, and the second color resist layer partially overlaps the first color resist layer.

In some embodiments, at least part of an orthographic projection of the second color resist layer on the display panel is outside the orthographic projections of the first openings on the display panel, and at least part of an orthographic projection of the first color resist layer on the display panel is outside the orthographic projections of the second openings on the display panel.

In some embodiments, light transmittance of the light-transmitting openings of the color filter layer is greater than or equal to 40%, and the light-shielding layer includes a material with an optical density greater than or equal to 1.5.

Beneficial effects of the present application are that, in the display panel of the present application, the light-transmitting openings of the color filter layer are formed from the overlapping portion of the first openings of the light-shielding layer and the second openings of the second color resist layer, so that the problems of poor shape uniformity of the first openings formed by the light-shielding layer and being easy to produce irregular edges or rough edges are thereby alleviated.

Moreover, the display panel of the present application is provided with the first color resist layer allowing transmittance of the first color and a second color resist layer allowing transmittance of the second color, the first color resist layer is at least disposed on the first openings corresponding to the first pixel openings, and the second color resist layer overlaps or contacts the first color resist layer and the light-shielding layer, thereby further determining the light-transmitting openings of the color filter layer and optimizing a color gamut of light emitted by the first light-emitting pixel units.

Further, a color separation phenomenon of the display panel can be further improved by setting a top view pattern of the light-transmitting openings of the color filter layer into a circle or a quasi-circular polygon.

### BRIEF DESCRIPTION OF DRAWINGS

In order to more clearly illustrate the technical solutions of the embodiments of the application, the drawings illustrating the embodiments will be briefly described below. Obviously, the drawings in the following description merely illustrate some embodiments of the present invention. Other drawings may also be obtained by those skilled in the art according to these figures without paying creative work.

FIG. 1 is a schematic perspective top view of light-transmitting openings of a color filter layer in an embodiment of the present application.

FIG. 2 is a schematic perspective top view of other light-transmitting openings of the color filter layer in an embodiment of the present application.

FIG. 3 is a schematic partial cross-sectional view of the display panel in the embodiment of the present application taken along line A-A′ of FIG. 2.

FIG. 4 is a schematic perspective top view of further light-transmitting openings of the color filter layer in an embodiment of the present application.

FIG. 5 is a schematic partial cross-sectional view of the display panel in the embodiment of the present application taken along line B-B′ of FIG. 4.

FIG. 6 is a schematic partial cross-sectional view of the display panel in the embodiment of the present application taken along line C-C′ in FIG. 4.

### DETAILED DESCRIPTION OF PREFERRED EMBODIMENTS

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application.

In the description of this application, it should be understood that the terms “center”, “longitudinal”, “transverse”, “length”, “width”, “thickness”, “upper”, “lower”, “front”, “Rear”, “left”, “right”, “vertical”, “horizontal”, “top”, “bottom”, “inside”, “outside”, “clockwise”, “counterclockwise”, and the like are based on the orientation or positional relationship shown in the drawings, and is merely for the convenience of describing the present invention and simplifying the description, rather than indicating or implying that the device or element referred to must have a specific orientation, structure and operation in a specific orientation, which should not be construed as limitations on the present invention. In addition, the terms “first” and “second” are used for descriptive purposes only, and cannot be understood as indicating or implying relative importance or implicitly indicating the number of technical features indicated. Therefore, the features defined as “first” and “second” may explicitly or implicitly include one or more of the features. In the description of the present application, the meaning of “a plurality” is two or more, unless specifically defined otherwise.

The following disclosure provides many different embodiments or examples for realizing different structures of the present application. To simplify the disclosure of the present application, the components and settings of specific examples are described below. Of course, they are only examples and are not intended to limit the application. In addition, the present application may repeat reference numerals and/or reference letters in different examples. Such repetition is for the purpose of simplification and clarity, and does not indicate the relationship between the various embodiments and/or settings discussed. In addition, this application provides examples of various specific processes and materials, but those of ordinary skill in the art may be aware of the applications of other processes and/or the use of other materials.

Technical solutions of the present application will now be described in conjunction with specific embodiments.

In the prior art, the OLED display panel made with POL-less technology uses a color filter (CF) instead of a polarizer, and the color filter has a matrix of RGB openings. When ambient light irradiates to the display panel, the light will enter through these openings and produce reflected light, which will interfere with each other and cause color separation.

In the prior art, the RGB openings are usually defined by a black matrix. Because non-opening areas are covered by the light-shielding layer, reflected light will be absorbed by the light-shielding layer. A shape of each of the RGB openings formed by the light-shielding layer will affect an intensity and an optical path difference of the reflected light. As a result, if the shape of the RGB opening is non-circular, such as a square, the optical path difference of the reflected light in the diagonal direction and the optical path difference of the reflected light in the short-side direction will be different. Therefore, the RGB openings of the non-circular shape will cause a very obvious color separation phenomenon in the display panel.

Moreover, due to material limitations of the light-shielding layer and the light absorption requirements, a process stability of the light-shielding layer is poor, and a material of the light-shielding layer is difficult to uniformly cure. Therefore, shape uniformity of the RGB openings formed by the light-shielding layer is poor, which may easily cause irregular edges or rough edges of the RGB openings, thereby negatively affecting the phenomenon of color separation.

Therefore, the present application provides a display panel, which is used to solve problems of poor shape uniformity of openings formed by the light-shielding layer and being easy to produce irregular edges or rough edges, and to further solve the color separation phenomenon of the OLED display panel manufactured by the POL-less technology in the prior art.

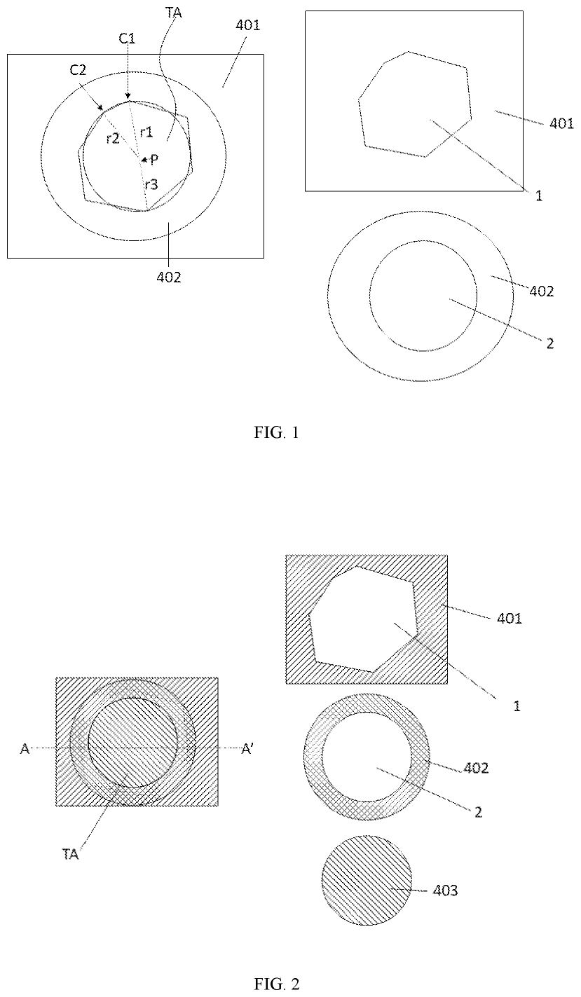

As shown in FIGS. 1 to 3, the display panel 100 includes a substrate (not shown), a light-emitting device layer 10, and a color filter layer 40. The substrate may be a flexible substrate or a glass substrate, and the light-emitting device layer 10 includes a pixel definition layer 102 and a light-emitting layer 101.

The pixel defining layer 102 includes a plurality of first pixel openings 3; the light-emitting layer 101 is disposed on the side of the pixel defining layer 102 away from the substrate, and the light-emitting layer 101 includes a plurality of first light-emitting pixel units 1011 displaying a first color and a plurality of second light-emitting pixel units (not shown) displaying a second color, the first light-emitting pixel units 1011 are arranged corresponding to the first pixel openings 3; the color filter layer 40 is arranged on the side of the pixel defining layer 102 away from the substrate, the color filter layer 40 includes a light-shielding layer 401, and the light-shielding layer 401 includes a plurality of first openings 1 arranged corresponding to the first pixel openings 3.

The color filter layer 40 further includes: a first color resist layer 403 allowing transmittance of the first color and a second color resist layer 402 allowing transmittance of the second color. The first color resist layer 403 is disposed at least in the first openings 1 corresponding to the first pixel openings 3, the second color resist layer 402 is disposed on a side of the light-shielding layer 401 away from the substrate, and the second color resist layer 402 and the first color resist layer 403 both overlap or are in contact with the light-shielding layer 401, and the second color resist layer 402 is also provided with second openings 2 corresponding to the first pixel openings 3, and overlapping portions between the first openings 1 and the second openings 2 form light-transmitting openings TA of the color filter layer 40.

The display panel of the present application forms the light-transmitting openings TA of the color filter layer 40 from the overlapping portions of the first openings 1 of the light-shielding layer 401 and the second openings 2 of the second color resist layer 402 to thereby alleviate problems of poor shape uniformity of openings formed by the light-shielding layer and being easy to produce irregular edges or rough edges.

Moreover, the display panel of the present application is provided with the first color resist layer 403 allowing transmittance of the first color and a second color resist layer 402 allowing transmittance of the second color, the first color resist layer 403 is at least disposed on the first openings 1 and corresponds to the first pixel openings 3, and the second color resist layer 402 overlaps or contacts the first color resist layer 403 and the light-shielding layer 401, thereby further determining the light-transmitting openings TA of the color filter layer 40 can be further determined, and optimizing a color gamut of light emitted by the first light-emitting pixel units 1011.

It can be understood that although the embodiment of the present application only shows the first light-emitting pixel units 1011 displaying the first color, in fact, the light-emitting layer 101 of the display panel of the present application also includes a plurality of second light-emitting pixel units (not shown) displaying a second color, and a plurality of third light-emitting pixel units (not shown) displaying a third color. The first light-emitting pixel units 1011, the second light-emitting pixel units, and the third light-emitting pixel units are arranged in an array with each other. In addition, the first color may be red, the second color may be green, and the third color may be blue.

For example, when the first color is red, the first color resist layer 403 is a red color resist layer, and the second color resist layer 402 can be a blue color resist layer or a green color resist layer.

It is appreciated that when the first color resist layer 403 is a red color resist layer, the first color emitted by the first light-emitting pixel units 1011 is also red, and accordingly, when the second color resist layer 402 is a blue or green color resist layer, the red light emitted by the first light-emitting pixel units 1011 will be absorbed by the second color resist layer 402 to form a non-transmissive area, and the second color resist layer 402 may further define the light-transmitting openings TA of the color filter layer 40.

It should be noted that since the process stability of the second color resist layer 402 of the non-black matrix is better, by overlapping the first openings 1 of the light-shielding layer 401 (i.e., the black matrix) with the second openings 2 of the second color resist layer 402, the second openings 2 of the second color resist layer 402 can further modify the first openings 1 of the light-shielding layer 401, thereby solving the problem of poor shape uniformity of the first openings formed by the light-shielding layer 401, and optimizing the shape of the light-transmitting openings TA of the color filter layer 40.

In addition, by disposing the first color resist layer 403 allowing transmittance of the first color in the light-transmitting openings TA of the color filter layer 40, a color gamut of the exiting light can be further optimized.

Further, in an embodiment of the present application, the light transmittance of the light-transmitting openings TA of the color filter layer 40 is greater than or equal to 40%. The light transmittance is the ratio of the luminous flux of the light emitted by the first light-emitting pixel units 1011 passing through the light-transmitting openings TA of the color filter layer 40 to the luminous flux of the light emitted by the first light-emitting pixel units 1011 within a wavelength range of 380-780 nm, that is, the ratio of the light emitted by the first light-emitting pixel units 1011 that can pass through the light-transmitting openings TA of the color filter layer 40 in the wavelength range of 380-780 nm.

It can be understood that setting the light transmittance of the light-transmitting openings TA of the color filter layer 40 to be greater than or equal to 40% can reduce the power consumption of the display panel.

Further, in an embodiment of the present application, the light-shielding layer 401 includes a material with an optical density (OD) greater than or equal to 1.5. The material with an optical density (OD) greater than or equal to 1.5 can be acrylic resin or other polymers doped with carbon black, black dye or black pigment, and is not particularly limited in the present application.

It can be understood that the light-shielding layer 401 includes a material with an optical density (OD) greater than or equal to 1.5 to ensure that the ambient light is completely absorbed by the light-shielding layer 401, thereby reducing reflection of ambient light.

Further, in an embodiment of the present application, the top view pattern of the light-transmitting openings TA of the color filter layer 40 includes a circle or a quasi-circular polygon. As shown in FIG. 1, the quasi-circular polygon includes multiple sides and inflection points (such as C1, C2) connecting two adjacent sides, and the quasi-circular polygon also includes a center point P, and distances from the center point to the multiple inflection points (such as C1 and C2) are all the same.

As shown in FIG. 1, the light-transmitting openings TA of the color filter layer 40 is formed by overlapping the first openings 1 of the light-shielding layer 401 and the second openings 2 of the second color resist layer 402. The quasi-circular polygon is defined as that distances from the intersection points of the first openings 1 and the second openings 2 (that is, the above-mentioned inflection points) to the center point P of the light-transmitting openings TA of the color filter layer 40 are all equal, that is, r1, r2, and r3 in the figure are equal to each other.

That is, the boundary line of the orthographic projection of the second openings 2 on the display panel and the boundary line of the orthographic projection of the first openings 1 on the display panel have multiple intersection points (that is, the above-mentioned inflection points), The orthographic projection of the light-transmitting openings TA on the display panel includes a central point P, and the distances from the multiple intersection points to the central point P are all equal.

Specifically, the shape of the first openings 1 and the second openings 2 may be circular, rectangular or irregular, as long as the shape of the orthographic projection of the light-transmitting opening TA of the color filter layer 40 formed by the overlapping portion of the first openings 1 and the second openings 2 on the display panel 100 is circular or quasi-circular polygon

Further, the first color resist layer 403 is disposed on the side of the second color resist layer 402 away from the substrate, or the first color resist layer 403 is disposed between the second color resist layer 402 and the light-shielding layers 401, and the first color resist layer 403 covers at least the area corresponding to the light-transmitting openings TA.

It is appreciated that although the drawings of the present application only show that the first color resist layer 403 is disposed between the second color resist layer 402 and the light-shielding layer 401, the position of the first color resist layer 403 in the cross-sectional direction is not limited thereto, and the first color resist layer 403 may also be disposed on the side of the second color resist layer 402 away from the substrate. In addition, covering the first color resist layer 403 at least the area corresponding to the light-transmitting openings TA can avoid light leakage of the pixels.

As shown in FIG. 2, the left side is a perspective top view schematic diagram of the color filter layer 40 after being stacked, and the right side is a schematic diagram of the light-shielding layer 401, the first color resist layer 403 and the second color resist layer 402, respectively.

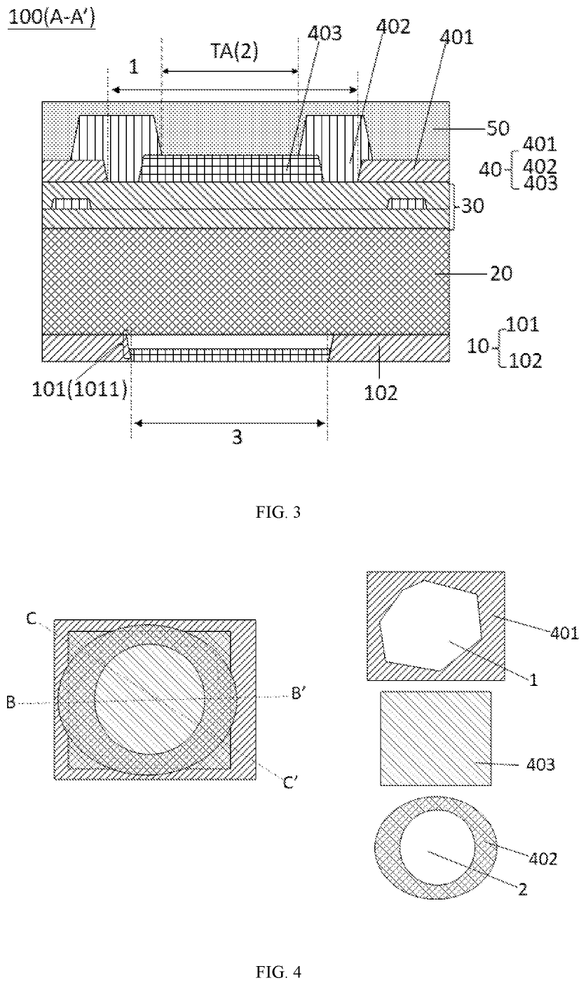

Further, in an embodiment of the present application, as shown in FIGS. 2 and 3, the orthographic projection of the second openings 2 on the display panel is located within the orthographic projection of the first openings 1 on the display panel.

In this embodiment, specifically, the top view pattern of the second openings 2 includes a circle and a quasi-circular polygon, and the quasi-circular polygon includes a plurality of sides and inflection points connecting two adjacent sides (such as C1, C2), the quasi-circular polygon further includes a central point P, and the distances from the central point P to the multiple inflection points (such as C1 and C2) are all the same. That is, the second openings 2 are directly the light-transmitting openings TA, and the light-transmitting openings TA of the color filter layer 40 are the same as the orthographic projection of the second openings 2 on the display panel.

It is appreciated that the light-transmitting openings TA of the color filter layer 40 can be completely defined by the second openings 2 through the above arrangement. Since the process stability of the second color resist layer 402 is better, the problem of poor shape uniformity of the first openings formed by the light-shielding layer 401 can be further solved, and the shape of the light-transmitting openings TA of the color filter layer 40 can be optimized.

It is appreciated that when orthographic projections of the light-transmitting openings TA of the color filter layer 40 on the display panel are same as orthographic projections of the second openings 2 on the display panel, the second openings 2 is circular or quasi-circular polygon.

It should be noted that although FIGS. 2 and 3 only show that the first color resist layer 403 is disposed between the second color resist layer 402 and the light-shielding layer 401, their positions in a cross-section are not particularly limited thereto, and the first color resist layer 403 may also be disposed on the side of the second color resist layer 402 away from the substrate. In addition, disposing the first color resist layer 403 at least an area corresponding to the light-transmitting opening TA can avoid light leakage of a pixel.

Further, the second color resist layer 402 partially overlaps the light-shielding layer 401, and specifically, at least part of an orthographic projection of the second color resist layer 402 on the display panel is outside the orthographic projections of the first openings 1 on the display panel.

As adopting such an arrangement in the present application, the second color resist layer 402 can further absorb the light emitted by the first light-emitting pixel units 1011 or reflected light of the ambient light, so that the light transmittance of an area where the second color resist layer 402 is disposed decreases, and thus the light transmission openings TA of the color filter layer 40 can be defined by the first openings 1 of the light-shielding layer 401 and the second color resist layer 402 together. Therefore, in an overlapping area of the light-shielding layer 401 and the second color resist layer 402, it can be further ensured that the ambient light is completely absorbed by the stack of the light-shielding layer 401 and second color resist layer 402, thereby reducing reflection of ambient light.

Further, the first light-emitting pixel units 1011 are located in the first pixel openings 3, and the first pixel openings 3 are greater than or equal to the light-transmitting openings TA of the color filter layer 40.

By setting the first pixel openings 3 to be greater than or equal to the light-transmitting openings TA of the color filter layer 40, a light-emitting area of the first light-emitting pixel units 1011 can be ensured, so that the light-emitting area can be determined by the light-transmitting openings TA of the color filter layer 40, thereby facilitating optimization of the shape of the light-transmitting openings TA of the color filter layer 40.

In an embodiment of the present application, the display panel further includes a thin-film encapsulation layer 20 and a touch electrode layer 30, the thin-film encapsulation layer 20 is disposed between the light-emitting device layer 10 and the color filter layer 40, and the touch electrode layer 30 is disposed between the thin film encapsulation layer 20 and the color filter layer 40.

Specifically, the thin film encapsulation layer 20 is configured to isolate water and oxygen from outside, so as to prevent the display panel 100 from failure. The thin film encapsulation layer 20 may include a first inorganic layer, an organic planarization layer, and a second inorganic layer that are stacked. A material of each of the first inorganic layer and the second inorganic layer includes at least one of silicon nitride or silicon oxide; a material of the organic planarization layer includes acrylic, etc., which is not particularly limited in the present application.

The touch electrode layer 30 is disposed on the thin film encapsulation layer 20 and configured to realize a touch function of the display panel 100.

Specifically, the touch electrode layer 30 has a metal mesh structure and is arranged between the light-transmitting openings TA of the color filter layer 40 to preventing impacting light emission of pixels.

Further, the display panel 100 may further include an organic protective layer 50, the organic protective layer 50 is configured to planarize the color filter layer 40 and protect the display panel 100, and a material of the organic protective layer 50 is an organic transparent material, such as a photoresist material, etc.

It is appreciated that the display panel 100 may further include a substrate (not shown) and a thin film transistor array layer (not shown), the thin film transistor array layer is disposed on the substrate, and the light-emitting device layer 10 is disposed on the thin film transistor array layer.

The substrate may be a glass substrate or a flexible substrate, which is not particularly limited in the present application.

The thin film transistor array layer includes inorganic stacked layers and a thin film transistor located in the inorganic stacked layers. The inorganic stacked layers include but are not limited to a gate insulating layer and an interlayer insulating layer, and the thin film transistor includes an active layer, a gate, and a source/drain. The thin film transistor array layer can be any well-known thin film transistor array layer, which is not particularly limited in the present application.

In another embodiment of the present application, as shown in FIG. 4 to FIG. 6, this embodiment has a similar structure to the above-mentioned embodiment, except that the second color resist layer 402 partially overlaps the first color resist layer 403. Specifically, at least part of the orthographic projection of the first color resist layer 403 on the display panel is outside the orthographic projections of the second openings 2 on the display panel.

Further, the orthographic projection of the first color resist layer 403 on the display panel 100 partially overlaps the orthographic projections of the second color resist layer 402 and the light-shielding layer 401 on the display panel 100.

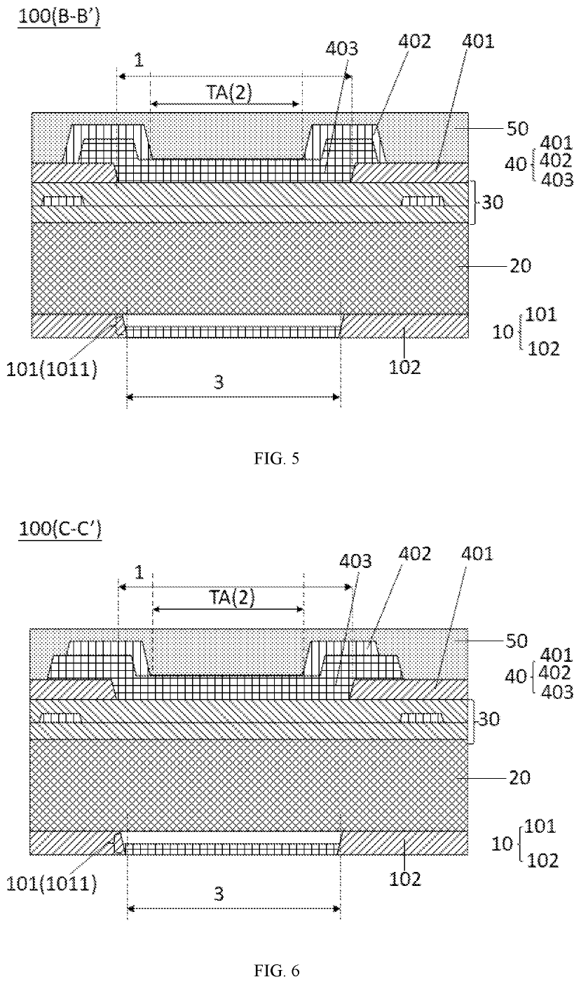

Specifically, as shown in FIGS. 5 and 6, the first color resist layer 403 extends from the light-transmitting openings TA of the color filter layer 40 to overlap the second color resist layer 402, or even extends to overlap the light-shielding layer 401. By overlapping the first color resist layer 403 and the second color resist layer 402, an overlapping area of the first color resist layer 403 and the second color resist layer 402 can be made to have a light-shielding effect as the light-shielding layer 401, thereby further ensuring that ambient light is completely absorbed by the stack of the first color resist layer 403 and second color resist layer 402, thereby further optimizing the light-transmitting openings TA of the color filter layer 40.

It should be noted that the display panel in the embodiments of the present application has a wide range of applications, including flexible OLED displays such as televisions, computers, mobile phones, and foldable and rollable OLEDs, and lighting, as well as wearable devices such as smart bracelets, smart watches, virtual reality (VR) devices, etc., which are all within the application fields of the display device in the embodiments of the present application.

In the above-mentioned embodiments, the description of each embodiment has its own emphasis, and parts that are not described in detail in an embodiment may be referred to related descriptions of other embodiments.

The embodiments of the present application have been described in detail above. Specific examples are used in this document to explain the principles and implementation of the present invention. The descriptions of the above embodiments are only for understanding the method of the present invention and its core ideas, to help understand the technical solution of the present application and its core ideas, and a person of ordinary skill in the art should understand that it can still modify the technical solution described in the foregoing embodiments, or equivalently replace some of the technical features. Such modifications or replacements do not depart the spirit of the corresponding technical solutions beyond the scope of the technical solutions of the embodiments of the present application.

What is claimed is:

1. A display panel, comprising:
a substrate;
a pixel definition layer disposed on a side of the substrate, wherein the pixel definition layer comprises a plurality of first pixel openings;
a light-emitting layer disposed on a side of the pixel definition layer away from the substrate, wherein the light-emitting layer comprises a plurality of first light-emitting pixel units displaying a first color and a plurality of second light-emitting pixel units displaying a second color, and the first light-emitting pixel units are arranged corresponding to the first pixel openings; and
a color filter layer disposed on the side of the pixel definition layer away from the substrate, wherein the color filter layer comprises a light-shielding layer, and the light-shielding layer comprises a plurality of first openings arranged corresponding to the first pixel openings,
wherein the color filter layer further comprises: a first color resist layer allowing transmittance of the first color and a second color resist layer allowing transmittance of the second color, the first color resist layer is at least disposed at the first openings corresponding to the first pixel openings, the second color resist layer is disposed on a side of the light-shielding layer away from the substrate, the second color resist layer and the first color resist layer overlap or contact with the light-shielding layer, the second color resist layer is also provided with second openings corresponding to the first pixel openings, and overlapping portions of the first openings and the second openings form light-transmitting openings of the color filter layer.

2. The display panel according to claim 1, wherein
a top view pattern of each of the light-transmitting openings of the color filter layer comprises a circle or a quasi-circular polygon, the quasi-circular polygon comprises a plurality of sides and a plurality of inflection points connecting adjacent ones of the sides, the quasi-circular polygon further comprises a center point, and distances from the center point to the plurality of inflection points are all equal.

3. The display panel according to claim 1, wherein a boundary line of an orthographic projection of one of the second openings on the display panel and a boundary line of an orthographic projection of one of the first openings on the display panel have a plurality of intersections, an orthographic projection of one of the light-transmitting openings on the display panel comprises a center point, and distances from the plurality of intersections to the center point are all equal.

4. The display panel according to claim 3, wherein the first color resist layer is disposed on a side of the second color resist layer away from the substrate, or the first color resist layer is disposed between the second color resist layer and the light-shielding layer, and the first color resist layer at least covers an area corresponding to the light-transmitting openings.

5. The display panel according to claim 1, wherein orthographic projections of the second openings on the display panel are located within orthographic projections of the first openings on the display panel.

6. The display panel according to claim 5, wherein a top view pattern of each of the second openings comprises a circle or a quasi-circular polygon, and the quasi-circular polygon comprises a plurality of sides and a plurality of inflection points connecting adjacent ones of the sides, the quasi-circular polygon further comprises a center point, and distances from the center point to the plurality of inflection points are all equal.

7. The display panel according to claim 5, wherein the first color resist layer is disposed on a side of the second color resist layer away from the substrate, or the first color resist layer is disposed between the second color resist layer and the light-shielding layer, and the first color resist layer covers at least an area corresponding to the second openings.

8. The display panel according to claim 7, wherein the second color resist layer partially overlaps the light-shielding layer, and the second color resist layer partially overlaps the first color resist layer.

9. The display panel according to claim 7, wherein at least part of an orthographic projection of the second color resist layer on the display panel is outside the orthographic projections of the first openings on the display panel, and at least part of an orthographic projection of the first color resist layer on the display panel is outside the orthographic projections of the second openings on the display panel.

10. The display panel according to claim 1, wherein light transmittance of the light-transmitting openings of the color filter layer is greater than or equal to 40%, and the light-shielding layer comprises a material with an optical density greater than or equal to 1.5.

11. A display panel, comprising:
a substrate;
a pixel definition layer disposed on a side of the substrate, wherein the pixel definition layer comprises a plurality of first pixel openings;
a light-emitting layer disposed on a side of the pixel definition layer away from the substrate, wherein the light-emitting layer comprises a plurality of first light-emitting pixel units displaying a first color and a plurality of second light-emitting pixel units displaying a second color, and the first light-emitting pixel units are arranged corresponding to the first pixel openings; and
a color filter layer disposed on the side of the pixel definition layer away from the substrate, wherein the color filter layer comprises a light-shielding layer, and the light-shielding layer comprises a plurality of first openings arranged corresponding to the first pixel openings,
wherein the color filter layer further comprises: a first color resist layer allowing transmittance of the first color and a second color resist layer allowing transmittance of the second color, the first color resist layer is at least disposed at the first openings corresponding to the first pixel openings, the second color resist layer is disposed on a side of the light-shielding layer away from the substrate, the second color resist layer and the first color resist layer overlap or contact with the light-shielding layer, the second color resist layer is also provided with second openings corresponding to the first pixel openings, and overlapping portions of the first openings and the second openings form light-transmitting openings of the color filter layer; and
wherein the first light-emitting pixel units are located in the first pixel openings, and the first pixel openings are greater than or equal to the light-transmitting openings of the color filter layer.

12. The display panel according to claim 11, wherein
a top view pattern of each of the light-transmitting openings of the color filter layer comprises a circle or a quasi-circular polygon, the quasi-circular polygon comprises a plurality of sides and a plurality of inflection points connecting adjacent ones of the sides, the quasi-circular polygon further comprises a center point, and distances from the center point to the plurality of inflection points are all equal.

13. The display panel according to claim 11, wherein a boundary line of an orthographic projection of one of the second openings on the display panel and a boundary line of an orthographic projection of one of the first openings on the display panel have a plurality of intersections, an orthographic projection of one of the light-transmitting openings on the display panel comprises a center point, and distances from the plurality of intersections to the center point are all equal.

14. The display panel according to claim 13, wherein the first color resist layer is disposed on a side of the second color resist layer away from the substrate, or the first color resist layer is disposed between the second color resist layer and the light-shielding layer, and the first color resist layer at least covers an area corresponding to the light-transmitting openings.

15. The display panel according to claim 11, wherein orthographic projections of the second openings on the display panel are located within orthographic projections of the first openings on the display panel.

16. The display panel according to claim 15, wherein a top view pattern of each of the second openings comprises a circle or a quasi-circular polygon, and the quasi-circular polygon comprises a plurality of sides and a plurality of inflection points connecting adjacent ones of the sides, the quasi-circular polygon further comprises a center point, and distances from the center point to the plurality of inflection points are all equal.

17. The display panel according to claim 15, wherein the first color resist layer is disposed on a side of the second color resist layer away from the substrate, or the first color resist layer is disposed between the second color resist layer and the light-shielding layer, and the first color resist layer covers at least an area corresponding to the second openings.

18. The display panel according to claim 17, wherein the second color resist layer partially overlaps the light-shielding layer, and the second color resist layer partially overlaps the first color resist layer.

19. The display panel according to claim 17, wherein at least part of an orthographic projection of the second color resist layer on the display panel is outside the orthographic projections of the first openings on the display panel, and at least part of an orthographic projection of the first color resist layer on the display panel is outside the orthographic projections of the second openings on the display panel.

20. The display panel according to claim 11, wherein light transmittance of the light-transmitting openings of the color filter layer is greater than or equal to 40%, and the light-shielding layer comprises a material with an optical density greater than or equal to 1.5.
